(19) United States
(12) Patent Application Publication
(10) Pub. No.: US 2015/0177188 A1
(43) Pub. Date: Jun. 25, 2015

(54) MICROFLUIDIC DEVICE

(71) Applicant: NATIONAL TAIWAN UNIVERSITY, Taipei City (TW)

(72) Inventors: Shiang-Chi LIN, Taipei City (TW); Pei-Wen YEN, Taipei City (TW); Yu-Lung SUNG, Taipei City (TW); Chih-Ting LIN, Taipei City (TW)

(73) Assignee: NATIONAL TAIWAN UNIVERSITY, Taipei City (TW)

(21) Appl. No.: 14/523,561

(22) Filed: Oct. 24, 2014

(30) Foreign Application Priority Data
Dec. 25, 2013 (TW) 102148269

(51) Int. Cl. G01N 27/447; B03B 5/48; B03C 7/02; B01L 3/00; B81B 1/00

(52) U.S. Cl. CPC G01N 27/44791; B01L 3/502761; B81B 1/00; B03C 7/02; B03B 5/48; B01L 2200/0668; B01L 2400/0418

(57) ABSTRACT

A microfluidic device includes an insulating substrate, an electrode array and a cover. The electrode array is disposed on the substrate for receiving a plurality of alternating current control signals each of which has a phase. The cover is disposed on the substrate and has a surface that faces the substrate and that cooperates with the substrate to define a microfluidic channel over the electrode array. The phases of the control signals differ from one another, such that liquid introduced into the microfluidic channel is driven to flow therethrough.

### CROSS-REFERENCE TO RELATED APPLICATION

This application claims priority of Taiwanese Patent Application No. 102148269, filed on Dec. 25, 2013.

### BACKGROUND OF THE INVENTION

1. Field of the Invention

The invention relates to a microfluidic device.

2. Description of the Related Art

Mobile health systems have recently drawn lots of interests due to their advantages, such as portability, low-power consumption, and easy integration. However, conventional mobile health systems lack sample preparation functions which are vital to medical diagnosis. Recently, microfluidic technology is incorporated in the mobile health systems for the sample-preparation purposes due to its low cost, small size, and easy integration. However, conventional microfluidic sample-preparation components still need additional flow-driving devices, such as syringe pumps. Moreover, the conventional microfluidic sample-preparation devices do not provide other functions, such as filtration abilities.

### SUMMARY OF THE INVENTION

Therefore, the object of the present invention is to provide a microfluidic device that can perform selective filtration function and electro-actuated self-pumping function.

Accordingly, a microfluidic device of the present invention includes an insulating substrate, an electrode array and a cover. The electrode array is disposed on the substrate for receiving a plurality of alternating current control signals each of which has a phase. The cover is disposed on the substrate and has a surface that faces the substrate and that cooperates with the substrate to define a microfluidic channel over the electrode array. The phases of the control signals differ from one another, such that liquid introduced into the microfluidic channel is driven to flow therethrough.

Preferably, the phases of the control signals differ from one another so as to cause travelling-wave electroosmosis (TWEO) to drive the liquid to flow through the microfluidic channel, and to induce a flow field in the microfluidic channel by particle-surface electroosmosis to counteract the flow of the liquid driven by the TWEO so as to trap particles of the liquid with a diameter larger than a predetermined size, which is related to amplitude values of the control signals, on the electrode array.

### BRIEF DESCRIPTION OF THE DRAWINGS

Other features and advantages of the present invention will become apparent in the following detailed description of the preferred embodiment with reference to the accompanying drawings, of which:

FIG. 1 is an exploded perspective view of a preferred embodiment of a microfluidic device according to the invention;

FIG. 2 is a perspective view of the preferred embodiment;

FIG. 3 is a simulation diagram, illustrating a flow velocity profile in association with a 10 μm particle within the microfluidic channel;

FIG. 4 is another simulation diagram, illustrating a flow velocity profile in association with a 6 μm particle within the microfluidic channel;

FIG. 5 is yet another simulation diagram, illustrating a flow velocity profile in association with a 1 μm particle within the microfluidic channel;

FIG. 6 is still another simulation diagram, illustrating a flow velocity profile in association with a 1 μm particle within the microfluidic channel;

FIGS. 7A-7C are diagrams for demonstrating locations of 6 μm particles which are trapped within the microfluidic channel at various points in time;

FIG. 7D is a graph illustrating the number of the trapped 6-μm particles with respect to locations in the microfluidic channel; FIGS. 8A-8C are diagrams for demonstrating locations of the 10 μm particles which are trapped within the microfluidic channel at various points in time;

FIG. 8D is a graph illustrating the number of trapped 10 μm particles with respect to locations in the microfluidic channel;

FIGS. 9A-9C are diagrams for demonstrating locations of 1 μm particles which are trapped within the microfluidic channel at various points in time;

FIG. 9D is a graph illustrating the number of the trapped 1 μm particles with respect to locations in the microfluidic channel;

FIGS. 10A-10C are diagrams for demonstrating locations of 1 μm particles trapped within the microfluidic channel at various points in time;

FIG. 10D is a graph illustrating the number of the trapped 1 μm particles with respect to locations in the microfluidic channel;

FIG. 11A is a diagram for illustrating locations of cancer cells (HL-60) which are trapped within the microfluidic channel; FIG. 11B is an enlarged view of a part of FIG. 11A where the cancer cells are trapped; and

FIG. 11C is a graph illustrating the number of trapped cancer cells within the microfluidic channel with respect to the locations in the microfluidic channel.

### DETAILED DESCRIPTION OF THE PREFERRED EMBODIMENT

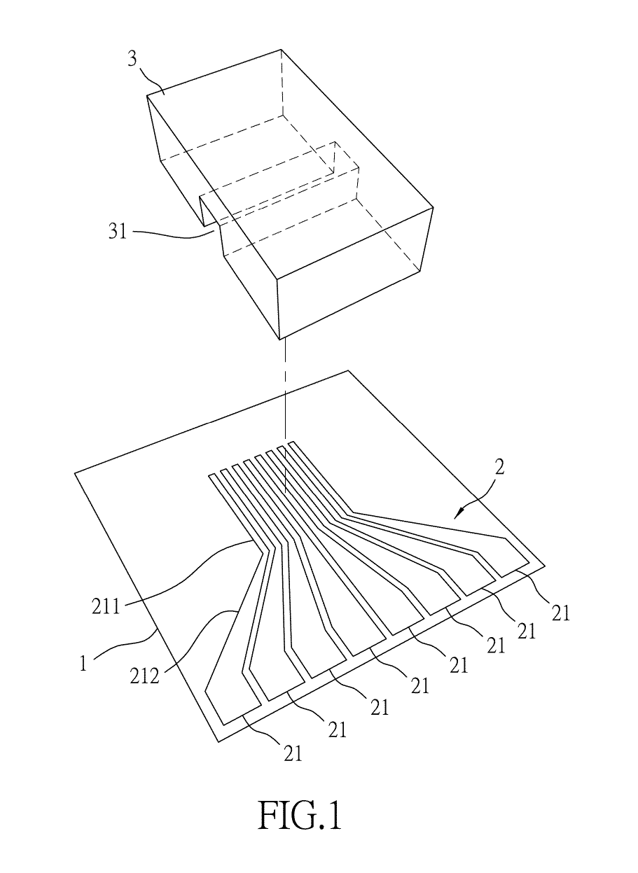

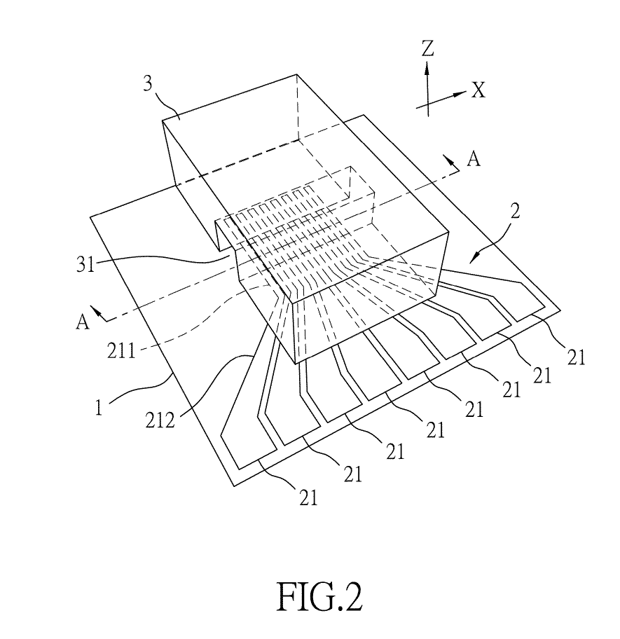

Referring to FIGS. 1 and 2, the preferred embodiment of a microfluidic device according to the present invention includes a substrate 1, an electrode array 2 and a cover 3.

The substrate 1 is made of an electrically insulating material. In this embodiment, the substrate 1 is made of glass.

The electrode array 2 is disposed on the substrate 1 for receiving a plurality of alternating current control signals each of which has a phase. The electrode array 2 includes a number N (N>1) of electrodes 21, each of which has an extending part 211, and a receiving part 212 that extends from the extending part 211.

As shown in FIG. 2, the extending parts 211 of the electrodes 21 are configured as strips which extend in an extending direction and which are parallel to and spaced apart from one another in a first direction (X) that is perpendicular to the extending direction. In this embodiment, the extending part 211 of each of the electrodes 21 has a length of about 800 μm and a width of 10 μm, and a gap between adjacent two of the extending parts 211 is 10 μm. It should be appreciated that dimensions of the extending parts 211 are not limited to the disclosure of this embodiment, and may be different in other embodiments of the present invention.

The receiving parts 212 of the electrodes 21 are adapted for receiving a number M (M>1) of the control signals that include first to M^{th} control signals, and the phase of the j^{th} control signal is smaller than the phase of the j+1^{th} control signal by 360/M degrees, where 1≦j≦(M−1). That is to say, the phases of the two control signals that are received respectively by adjacent two of the receiving parts 212 of the electrodes 21 differ from each other by 360/M degrees. In addition, the i^{th} electrode (1≦i≦N) is adapted for receiving the j^{th} control signal (1≦j≦M), where j is equal to M when i is a multiple of j, and is a remainder after i is divided by M when otherwise.

For example, when N=64 and M=4, the phases of the first to fourth control signals are θ°, θ+90°, θ+180°, and θ+270°, respectively. The electrodes 21 are divided into 16 groups each including four of the electrodes 21 that are adjacent one by one in the first direction (X), and the receiving parts 211 of first to fourth ones of the electrodes 21 in each of the groups receive the first to fourth control signals, respectively.

The cover 3 is disposed on the substrate 1, and has a surface that faces the substrate 1 and that cooperates with the substrate 1 to define a microfluidic channel 31 over the electrode array 2. To be specific, the microfluidic channel 31 extends in the first direction (X), and is disposed over the extending parts 211 of the electrodes 21. In this embodiment, the cover 3 is made of polydimethylsiloxane (PDMS), and is configured in a cuboid shape having a length of 300 μm, a width of 300 μm, and a height of 50 μm. However, the dimensions of the cover 3 are not limited to the disclosure of this embodiment, and may be different in other embodiments of the present invention.

The phases of the control signals differ from one another so as to cause travelling wave electroosmosis (TWEO) to drive liquid, which is introduced into the microfluidic channel 31, to flow through the microfluidic channel 31. In addition, a particle surface electroosmosis flow field is also induced by the control signals in the microfluidic channel 31 to counteract the flow of the liquid driven by the TWEO so as to trap particles of the liquid with a diameter larger than a predetermined size, which is related to an amplitude value of the control signals, within the microfluidic channel 31.

In greater detail, when the electrode array 2 receives the control signals, and a solution containing a plurality of particles is introduced into an open inlet of the microfluidic channel 31, each of the particles in the solution is subjected to two types of electrokinetic phenomena:

1. Travelling Wave Electroosmosis (TWEO):

The phases of the controls signals, which differ from one another, cause a travelling wave to drive the particles in the solution to flow along a predetermined direction. To be specific, since in this embodiment the extending parts 211 of the electrodes 21 are arranged in the first direction (X) of the microfluidic channel 31, the travelling wave travels through the microfluidic channel 31, and ions (or electrolytes) are driven to flow through the microfluidic channel 31 due to AC electric fields induced by the extending parts 211 of the electrodes 21, so as to form a Couette flow dragging the particles in the solution to flow into and through the microfluidic channel 31.

2. Particle Surface Electroosmosis (PSE):

When the solution flows into the microfluidic channel 31 due to the traveling-wave electroosmosic flow, the particles are dragged to be proximate to the extending parts 211 of the electrodes 21. As the particles approach closely to the electrodes 21 (especially boundary edges of each of the extending parts 211), effect of the electroosmosis near the particle surface becomes significant, so as to generate a flow field to counteract the flow driven by the TWEO, thereby trapping the particles in the gaps among the extending parts 211 of the electrodes 21.

It should be noted that the particles in the solution are not limited to carry positive or negative charges. In certain embodiments, the particles may be dielectric.

### [Simulations of TWEO+PSE]

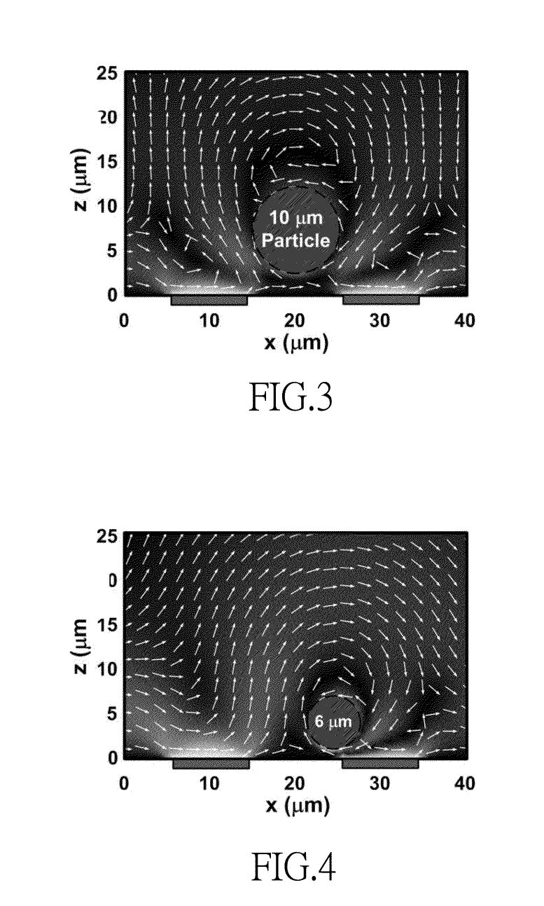

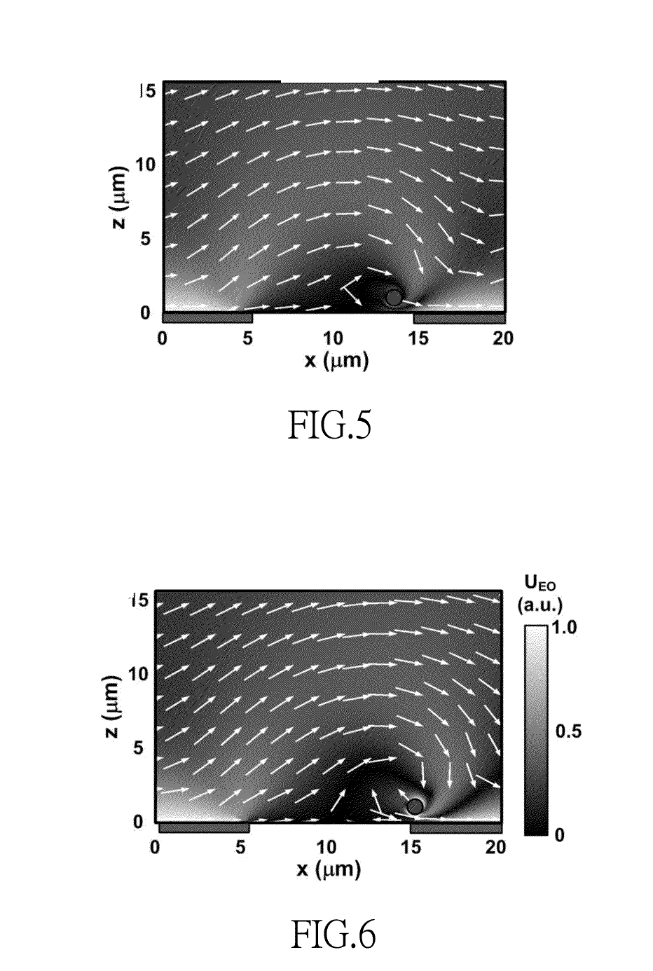

FIGS. 3, 4, and 5 are simulation diagrams, illustrating flow velocity profiles respectively of a 10 μm particle (i.e., FIG. 3), a 6 μm particle (i.e., FIG. 4), and a 1 μm particle (i.e., FIG. 5) within the microfluidic channel 31 under application of the control signals to the electrodes 21. Each of the four control signals has an amplitude value of 0.75 Volt and a frequency of 1000 Hz. In each of FIGS. 3 to 5, arrows represent directions of movement of the corresponding particle with respect to locations in the microfluidic channel 31, and gray scale represents speed of the movement. It should be noted that the effective region of the induced PSE flow is proportional to the particle surface area. Therefore, with decrease of the particle diameter (i.e., decrease of the particle surface area), the particles need to be closer in position to the electrodes 21 for inducing sufficient backward PSE flow to counteract and even out TWEO flow, so as to generate the trapping effect. It is clearly shown in FIGS. 3 and 4 that effective region of the induced PSE flow become smaller with decrease of the particle diameter, and the 6 μm particle shown in FIG. 4 may be trapped when in position closer to the extending parts 211 of the electrodes 21 in comparison to the 10 μm particle. However, as shown in FIG. 5, the 1 μm particle cannot induce sufficiently strong PSE flow to generate the trapping effect due to the particle size.

FIG. 6 is yet another simulation diagram that is similar to FIG. 5. Difference between the simulations in FIGS. 5 and 6 resides in that the amplitude value of each of the four control signals is 1.5 Volts for the simulation in FIG. 6. Since stronger PSE flow will be induced by the control signals that have a greater amplitude value, when the amplitude value of the control signals is greater than a predetermined value, the induced PSE flow will be strong enough to cancel out the dragging force induced by TWEO flow, so as to retain the particle between the electrodes 21 within the microfluidic channel 31 like the simulation result of FIG. 6.

### [Experiment 1]

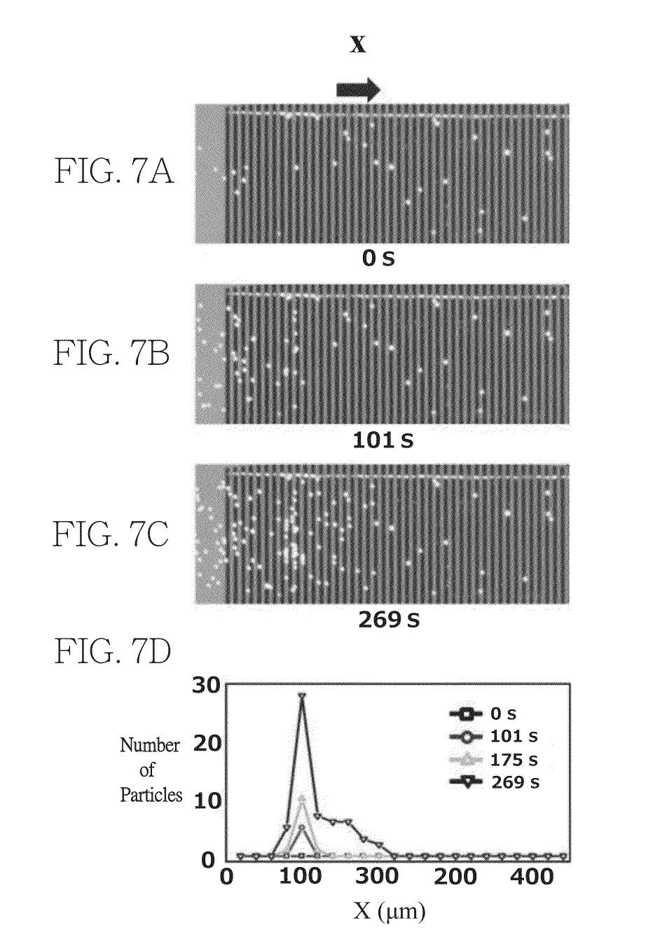

FIGS. 7A-7D show experimental results of a 100 μM potassium chloride (KCl) solution containing 6-μm fluorescent beads being steadily pumped into the microfluidic channel 31 and filtered by the electrode array 2, where the receiving parts 212 of the 9^{th} to 40^{th} electrodes 21 were provided with the control signals having an amplitude of 0.75 Volt and a frequency of 1000 Hz. Time sequence images as FIGS. 7A-7C were captured in order to track the 6-μm fluorescent polystyrene beads being dragged and trapped within the microfluidic channel 31 at various points in time (0 second, 101 seconds, and 269 seconds) during pumping and filtering. FIG. 7D shows a statistical result of the number of 6-μm fluorescent beads with respect to the locations thereof at various points in time. It is clearly shown that the KCl solution with the 6-μm fluorescent beads was driven by the control signals to steadily flow into the microfluidic channel 31 from the open inlet, and the 6-μm fluorescent beads in the KCl solution were trapped by the electrode array 2 so as to be retained in the microfluidic channel 31.

It should be noted that the first to eighth electrodes 21 did not receive any of the control signals for comparison. In addition, light spots depicted in FIG. 7A are pollutants instead of the 6-μm fluorescent beads, which exist in the microfluidic channel 31 from the very beginning, so are the light spots at the corresponding locations in FIGS. 7B and 7C.

### [Experiment 2]

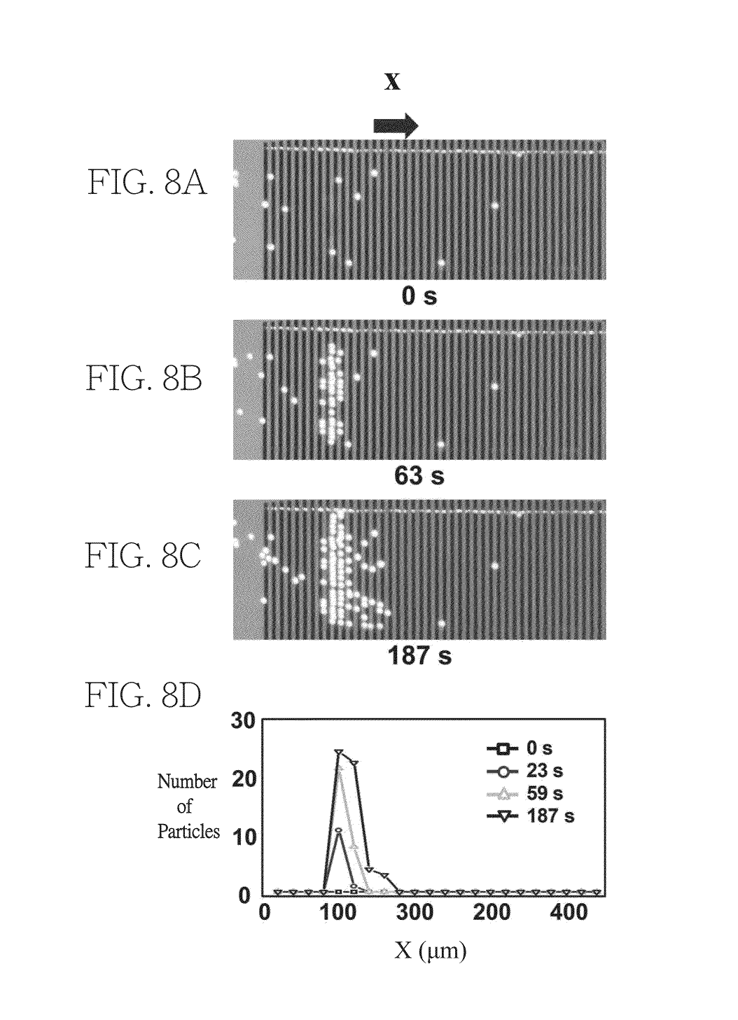

FIGS. 8A-8D show experimental results of a 100 μM KCl solution containing 10-μm fluorescent beads being steadily pumped into the microfluidic channel 31 and filtered by the electrode array 2, where the receiving parts 212 of the 9^{th} to 40^{th} electrodes 21 were provided with the control signals having an amplitude of 0.75 Volt and a frequency of 1000 Hz. Time sequence images as FIGS. 8A-8C were captured in order to track the 10-μm fluorescent beads being dragged and trapped within the microfluidic channel 31 at various points in time (0 second, 63 seconds, and 187 seconds) during pumping and filtering. FIG. 8D shows a statistical result of the number of 10-μm fluorescent beads with respect to the locations thereof at various points in time. Similarly, the 10-μm fluorescent beads in the KCl solution were capable of being trapped in the microfluidic channel 31 by the electrode array 2.

### [Experiment 3]

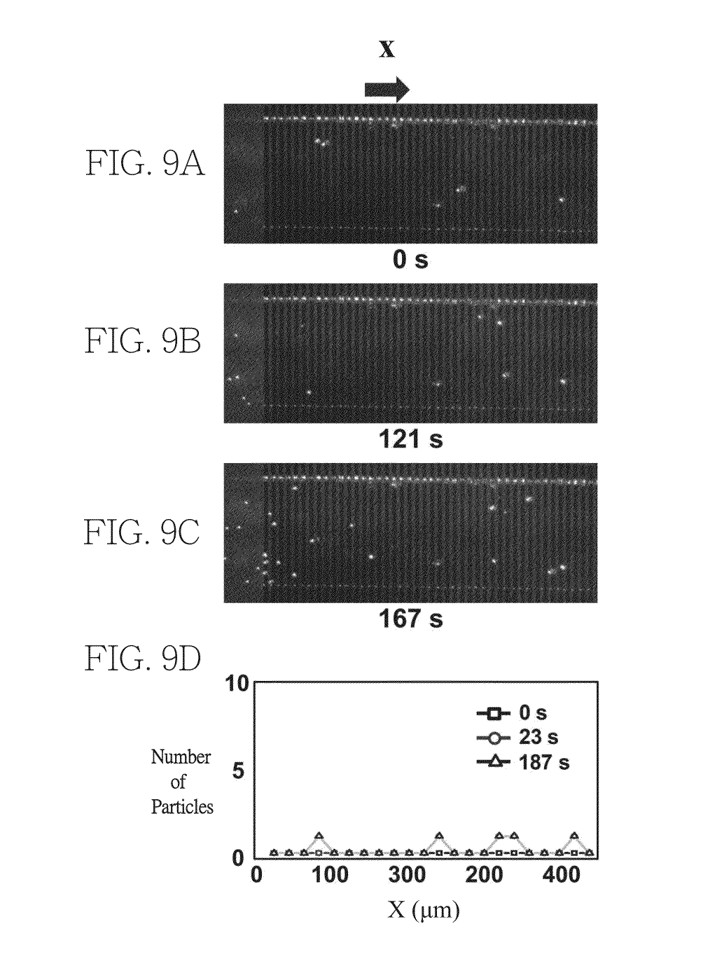

FIGS. 9A-9D show experimental results of a 100 μM KCl solution containing 1-μm fluorescent beads being pumped into the microfluidic channel 31 and filtered by the electrode array 2, where the receiving parts 212 of the 9^{th} to 40^{th} electrodes 21 were provided with the control signals having an amplitude of 0.75 Volt and a frequency of 1000 Hz. Time sequence images as FIGS. 9A-9C were captured in order to track the 1-μm fluorescent beads being dragged and trapped within the microfluidic channel 31 at various points in time (0 second, 121 seconds, and 167 seconds) during pumping and filtering. FIG. 9D shows a statistical result of the number of 1-μm fluorescent beads with respect to the locations thereof at various points in time. As shown in FIGS. 9A-9D, it is clear that only very few of the 1-μm fluorescent beads can be trapped within the microfluidic channel 31 by the electrode array 2.

### [Experiment 4]

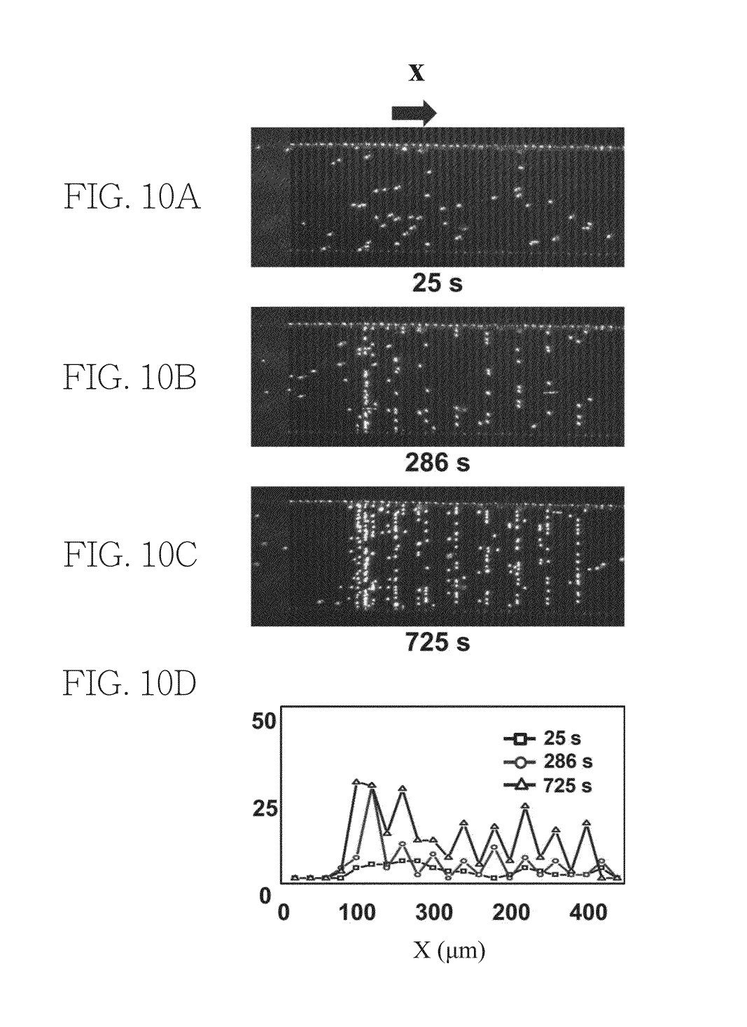

FIGS. 10A-10D show experimental results of a 100 μM KCl solution containing 1-μm fluorescent beads being pumped into the microfluidic channel 31 and filtered by the electrode array 2, where the receiving parts 212 of the 9^{th} to 40^{th} electrodes 21 were provided with the control signals having an amplitude of 1.5 Volts and a frequency of 1000 Hz. Time sequence images as FIGS. 10A-10C were captured in order to track the location of the 1-μm fluorescent beads trapped within the microfluidic channel 31 at various points in time (25 seconds, 286 seconds, and 725 seconds) during pumping and filtering. FIG. 10D shows a statistical result of the number of 1-μm fluorescent beads with respect to the locations thereof at various points in time. In comparison to the Experiment 3, the 1-μm fluorescent beads were capable of being trapped within the microfluidic channel 31 by the electrode array 2.

### [Experiment 5]

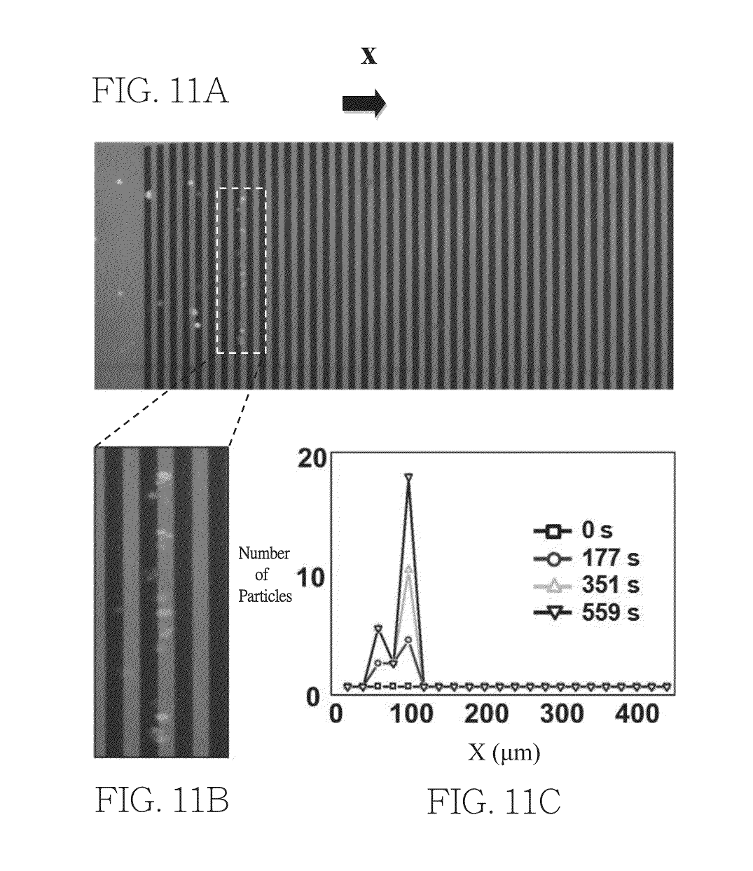

FIGS. 11A-11C show experimental results of 100 μM KCl solution (using 5 wt % of glucose solution as a solvent), which contains prior-stained human promyelocytic leukemia cells (HL-60), being pumped into the microfluidic channel 31 and filtered by the electrode array 2, where the receiving parts 212 of the 9^{th} to 40^{th} electrodes 21 were provided with the control signals having an amplitude value of 0.75 Volts and a frequency of 1000 Hz. The sizes of the stained HL-60 cancer cells range from 8 μm to 22 μm. FIG. 11A is a photograph captured at 559 seconds after introducing the solution into the microfluidic channel 31, showing that the HL-60 cells were selectively trapped within the microfluidic channel 31, FIG. 11C shows a statistical result of the number of the HL-60 cells with respect to the locations thereof at various points in time (0 second, 177 seconds, 351 seconds, and 559 seconds).

In view of Experiments 1 to 5, when the control signals are applied to the electrode array 2, particles having various diameters in the solution can be selectively trapped in the microfluidic channel 31 based on the amplitude value of the control signals. That is, by tuning the amplitude value of the control signals, the microfluidic device of the present invention is capable of selectively trapping particles (or cells) having a diameter larger than a predetermined value based on the amplitude value of the applied control signals. In addition, the microfluidic device can be implemented by standard CMOS process, so that it is relatively simple to incorporate the microfluidic device of the present invention with other biosensors which are manufactured using the standard CMOS process as well.

While the present invention has been described in connection with what is considered the most practical and preferred embodiment, it is understood that this invention is not limited to the disclosed embodiment but is intended to cover various arrangements included within the spirit and scope of the broadest interpretation so as to encompass all such modifications and equivalent arrangements.

What is claimed is:

1. A microfluidic device comprising:
an insulating substrate;
an electrode array disposed on said substrate for receiving a plurality of alternating current control signals each of which has a phase; and
a cover disposed on said substrate and having a surface that faces said substrate and that cooperates with said substrate to define a microfluidic channel over said electrode array;
wherein the phases of the control signals differ from one another such that liquid introduced into said microfluidic channel is driven to flow through said microfluidic channel.

2. The microfluidic device as claimed in claim 1, wherein the phases of the control signals differ from one another so as to cause travelling-wave electroosmosis (TWEC) to drive the liquid to flow through said microfluidic channel, and particle-surface electroosmosis to induce a flow field in said microfluidic channel to counteract the flow of the liquid driven by the TWEC so as to trap particles of the liquid with a diameter larger than a predetermined size, which is related to amplitude values of the control signals, on said electrode array.

3. The microfluidic device as claimed in claim 1, wherein said electrode array is adapted for receiving a number M (M>1) of the control signals that include first to M^{th} control signals, and the phase of the j^{th} control signal is smaller than the phase of the (j+1)^{th} control signal by 360/M degrees, where 1≦j≦(M−1).

4. The microfluidic device as claimed in claim 3, wherein said electrode array includes a plurality of electrodes arranged in a first direction, and the phases of two of the control signals that are received respectively by adjacent two of said electrodes differ from each other by 360/M degrees.

5. The microfluidic device as claimed in claim 3, wherein said electrode array includes a number N (N>1) of electrodes, each of which is adapted for receiving one of the control signals and has an extension part, said extension parts respectively of said electrodes being parallel to and spaced apart from one another in a first direction, and extending in a second direction perpendicular to the first direction.

6. The microfluidic device as claimed in claim 5, wherein said microfluidic channel in said cover is disposed over said extension parts and is parallel to the first direction.

7. The microfluidic device as claimed in claim 5, wherein said electrodes include first to N^{th} electrodes arranged sequentially in the first direction, and the i^{th} electrode (1≦i≦N) is adapted for receiving the j^{th} control signal (1≦j≦M), where j is equal to M when i is a multiple of j, and is a remainder after i is divided by M when otherwise.

8. The microfluidic device as claimed in claim 2, wherein the amplitude values respectively of the control signals are substantially the same.
